(19) United States
(12) Patent Application Publication
(10) Pub. No.: US 2021/0288256 A1
(43) Pub. Date: Sep. 16, 2021

(54) OLED DEVICE STRUCTURE, OLED DISPLAY PANEL AND DISPLAY DEVICE

(71) Applicant: Xianyang Caihong Optoelectronics Technology Co., Ltd., Xianyang (CN)

(72) Inventors: QIZHE CAI, XIANYANG (CN); YUANYUAN QI, XIANYANG (CN)

(21) Appl. No.: 17/190,709

(22) Filed: Mar. 3, 2021

(30) Foreign Application Priority Data
Mar. 16, 2020 (CN) 2020101824818

(51) Int. Cl. H01L 51/00; H01L 51/52

(52) U.S. Cl. CPC H01L 51/0037; H01L 51/0072; H01L 51/0069; H01L 51/006; H01L 51/0068; H01L 51/5056; H01L 51/0082; H01L 51/0092; H01L 51/5206; H01L 51/5221; H01L 51/0081

(57) ABSTRACT

An OLED device structure, an OLED display panel and a display device are provided. The OLED device structure includes: a first electrode; a self-assembled layer, disposed on the first electrode; a first transportation layer, disposed on the self-assembled layer; a light-emitting layer, disposed on the first transportation layer; a second transportation layer, disposed on the light-emitting layer; and a second electrode, disposed on the second transportation layer. The OLED display panel and the display device each include the OLED device structure. By setting a self-oriented self-assembled layer in the OLED device structure and selecting specific materials, advantages can be achieved as follows: an injection efficiency of hole is improved, a driving voltage is reduced, mobilities of electron and hole are increased, a luminous efficiency is increased, an external light coupling efficiency is increased, a light extraction rate is increased, and an external quantum efficiency is improved.

### TECHNICAL FIELD

The disclosure relates to the field of display technologies, and more particularly to an OLED device structure, an OLED display panel and a display device.

### DESCRIPTION OF RELATED ART

With the continuous improvement of people's living standards, a market demand of large area, ultra-thin and flexible intelligent display technology of a display panel and a lighting system will gradually become the urgent demand of people's life. The global demand for LCD (Liquid-crystal display) panels has stagnated and is facing crisis of overcapacity. New display technology has become the focus of research and development of major companies. Among them, an organic light-emitting diode (OLED) has been widely concerned and rapidly developed by the scientific community because of its low driving voltage, high efficiency, fast response speed, wide viewing angle, thin, large area and flexible display.

The existing OLED displays mainly have two kinds of bottom emission and top emission. The bottom emission OLED display device emit light from the TFT (thin film transistor) substrate side of the driving backplane after passing through the anode ITO, while the top emission OLED display device emit light through the cathode of OLED device. The structure of a general OLED device is shown in FIG. 1, it is usually composed of a glass substrate, a anode of a good light-transmitting indium tin oxide (ITO), a hole transportation layer (HTL), an organic light-emitting layer or an light-emitting layer (EML), an electron transportation layer (ETL) and a cathode of metal aluminum, silver or gold; in order to further optimize the performance of the OLED device, add another hole injection layer (HIL) before the hole transportation layer and add another electron injection layer (EIL) before the electron transportation layer. Single layer can be directly stacked for a single device, and all those layers can be stacked many times for a tandem device.

The energy level structure of the OLED device is shown in FIG. 2, electrons are injected from the metal cathode and holes are injected from the ITO anode, they pass through the electron transportation layer and the hole transportation layer respectively, and then combine in the light-emitting layer to form an excited state light emitting.

Except for the anode and the cathode, all layers of the existing OLED device always use the all organic materials, and the organic materials all have the problem of difficulty in charge injection current, especially between the hole injection layer and the anode, and these problems lead to high driving voltage, serious internal friction of the material, and shortened device life. Therefore, a high-efficiency and long-life OLED device not only needs to improve the material, but also needs to optimize the device structure design.

### SUMMARY

Accordingly, in order to overcome at least some defects and deficiencies in related art, embodiments of the disclosure provide an OLED device structure, an OLED display panel and a display device.

Specifically, an embodiment of the disclosure provides an OLED device structure including: a first electrode; a self-assembled layer, disposed on the first electrode; a first transportation layer, disposed on the self-assembled layer; a light-emitting layer, disposed on the first transportation layer; a second transportation layer, disposed on the light-emitting layer; and a second electrode, disposed on the second transportation layer.

In an embodiment of the disclosure, further including: a first injection layer, disposed between the first transportation layer and the self-assembled layer; and a second injection layer, disposed between the second transportation layer and the second electrode; a material of the self-assembled layer is prone to be horizontally oriented during a manufacturing process of the self-assembled layer.

In an embodiment of the disclosure, the material of the self-assembled layer includes heterocyclic conjugated long-chain linear molecules containing nitrogen or sulfur; and the manufacturing process of the self-assembled layer is an evaporation process or a solution coating process.

In an embodiment of the disclosure, the heterocyclic conjugated long-chain linear molecules containing nitrogen or sulfur include: 4,4′-Bis[4-(diphenylamino)styryl] biphenyl; 4-(2,2-diphenylethyl)-N, N-bis(4-tolyl)aniline; 4,4′-Bis(N-carbazolyl)biphenyl; poly(3,4-ethylenedioxythiophene):poly(styrenesulfonate); and 1,3-Bis[2-(2,2′-bipyridine-6)-1,3,4-oxadiazo-5]benzene.

In an embodiment of the disclosure, the first electrode is an anode, the first injection layer is a hole injection layer, the first transportation layer is a hole transportation layer, the second transportation layer is an electron transportation layer, the second injection layer is an electron injection layer, and the second electrode is a cathode.

In an embodiment of the disclosure, a material of the anode includes one or more selected from the group consisting of: indium tin oxide, indium zinc oxide, and zinc oxide; a material of the hole injection layer includes one or more selected from the group consisting of: 29H, 31H-phthalocyaninato(2-)-N29, N30, N31, N32)copper, and 4, 4′, 4″-tris[2-naphthyl(phenyl)amino]triphenylamine; a material of the hole transportation layer includes one or more selected from the group consisting of: N, N′-bis-(1-naphthalenyl)-N, N′-bis-phenyl-(1,1′-biphenyl)-4, 4′-diamine, N, N′-bis(phenyl)-N, N′-bis(4′-(N, N-bis(phenylamino)biphenyl-4-yl)benzidine, N, N′-bis(3-methylphenyl)-N, N′-diphenyl-9,9-spirobifluorene-2,7-diamine, 2(2(4, 4-dimethyl-N, N′-diphenyl)-phenylthiophene, 1, 3, 5-tris(phenylamino)benzene, 1, 3, 5-tri(p-pyrid-3-yl-phenyl)benzene, N1-phenyl-N4,N4-bis(4-(phenyl(m-tolyl)amino)phenyl)-N1-(m-tolyl)benzene-1, 4-diamine, 1, 3, 5-tris(diphenylamino)benzene, and 4,4′,4″-tris(N-3-methylphenyl-N-diphenylamino) benzene; a material of the electron transportation layer includes one or more selected from the group consisting of: metal chelates, quinoline derivatives, oxaline derivatives, diazaanthracene derivatives and phenanthroline derivatives; a material of the electron injection layer includes one or more selected from the group consisting of: lithium oxide, lithium boron oxide, potassium silicon oxide, potassium carbonate, cesium carbonate, acetate (CH3COOR), and metal fluoride (RF); a material of the cathode includes one or more selected from the group consisting of: aluminum, magnesium-silver alloy, and lithium aluminum alloy.

In an embodiment of the disclosure, the metal chelates include:

8-hydroxyquinoline M salt, fluorinated hydroxyquinoline aluminum, aluminum oxadiazole (Al(OXD)3), and 8-hydroxyquinoline zinc; the oxaline derivatives comprise: bis(phenylquinoxaline) and tris(phenylquinoxaline).

In an embodiment of the disclosure, the R of the acetate (CH3COOR) includes: lithium (Li), sodium (Na), potassium (K), rubidium (Rb) or cesium (Cs); the R of the metal fluoride (RF) includes: Li, Na, K, Rb or Cs; and the M of the 8-Hydroxyquinoline M salt includes: aluminum (Al), gallium (Ga), or indium (In).

In addition, an embodiment of the disclosure provides an OLED device panel including one of the OLED device structures mentioned above.

In addition, an embodiment of the disclosure provides a display device, including: the OLED display panel mentioned above.

The disclosure can achieve the following effects by setting the self-oriented self-assembled layer in the OLED device structure and selecting specific materials:

1. Reduce the surface energy of ITO substrate, through a weak intermolecular force (hydrogen bond), an ITO work function is reduced, a Homo (Highest Occupied Molecular Orbital) of the HIL is improved, an energy gap between the ITO substrate and the HIL is reduced, a hole injection efficiency is improved, and a drive voltage is reduced;

2. Increase the mobilities of the electrons and the holes are increased by the π-π conjugation between the self-assembled layer and the HIL, and then a luminous efficiency is increased;

3. In order to improve an external quantum efficiency, the horizontally oriented molecules are disposed on the surface of the ITO substrate to increase an external light coupling efficiency and a light extraction rate.

### BRIEF DESCRIPTION OF THE DRAWINGS

In order to more clearly illustrate technical solutions of embodiments of the disclosure, drawings used in the description of the embodiments will be briefly described below. Apparently, the drawings described below are merely some embodiments of the disclosure, and those skilled in the art can obtain other drawings based on these drawings without creative efforts.

FIG. 1 is a schematic structural view of an OLED device in related art.

FIG. 2 is a schematic structural view of energy level of the OLED device in related art.

FIG. 3 is a schematic structural view of an OLED device structure according to an embodiment of the disclosure.

FIG. 4a is a schematic structural view of another OLED device structure according to an embodiment of the disclosure.

FIG. 4b is a schematic structural view of energy level of the OLED device structure according to an embodiment of the disclosure.

FIG. 5a is a schematic view of a chemical structure of BDAVBi in an embodiment.

FIG. 5b is a schematic view of a chemical structure of PEBA in an embodiment.

FIG. 5c is a schematic view of a chemical structure of CBP in an embodiment.

FIG. 5d is a schematic view of a chemical structure of PEDOT:PSS in an embodiment.

FIG. 5e is a schematic view of a chemical structure of Bpy-OXD in an embodiment.

FIG. 6a is a schematic view of a chemical structure of NPB in an embodiment.

FIG. 6b is a schematic view of a chemical structure of TPTE in an embodiment.

FIG. 6c is a schematic view of a chemical structure of spiro-TAD in an embodiment.

FIG. 6d is a schematic view of a chemical structure of BFA-1T in an embodiment.

FIG. 6e is a schematic view of a chemical structure of TDAB in an embodiment.

FIG. 6f is a schematic view of a chemical structure of TDAPB in an embodiment.

FIG. 6g is a schematic view of a chemical structure of PTDATA in an embodiment.

FIG. 6h is a schematic view of a chemical structure of p-DPA-TDAB in an embodiment.

FIG. 6i is a schematic view of a chemical structure of MTBDAB in an embodiment.

FIG. 7a is a schematic view of chemical structures of metal chelates in an embodiment.

FIG. 7b is a schematic view of chemical structures of quinoline derivatives in an embodiment.

FIG. 7c is a schematic view of chemical structures of oxaline derivatives in an embodiment.

FIG. 7d is a schematic view of chemical structures of diazanthracene derivatives in an embodiment.

FIG. 7e is a schematic view of chemical structures of phenanthroline derivatives in an embodiment.

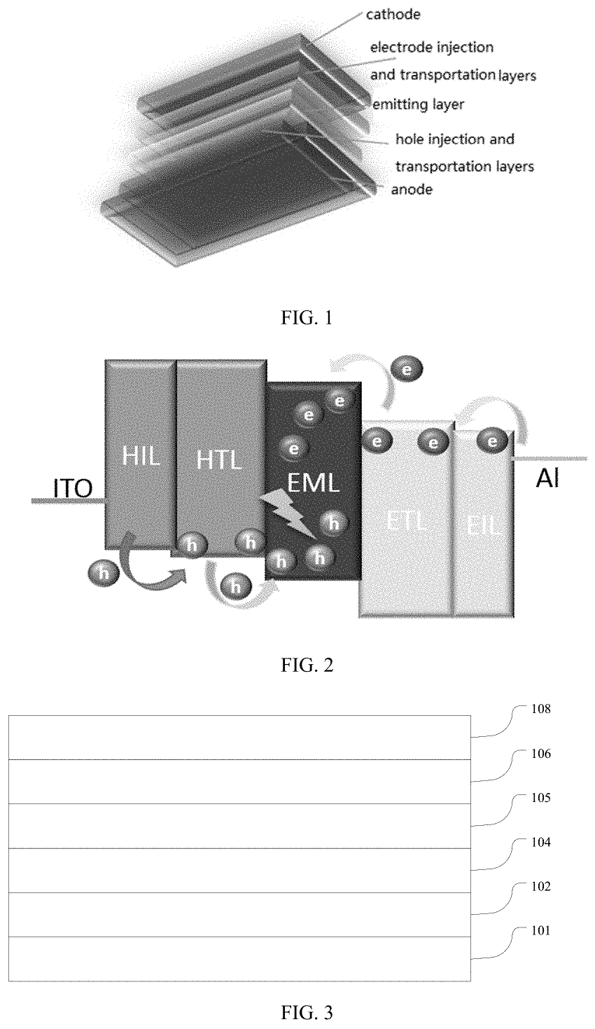

### DETAILED DESCRIPTION OF EMBODIMENTS

The technical solutions in the embodiments of the disclosure will be clearly and completely described below, with reference to the accompanying drawings in the embodiments of the disclosure. Apparently, the described embodiments are merely some of the embodiments of the disclosure, not all embodiments. Based on the described embodiments of the disclosure, all the other embodiments obtained by those skilled in the art without any creativity should belong to the protection scope of the disclosure.

An illustration of each of the following examples is provided with reference to the appended schemata, exemplifying the particular examples that are publicly available for implementation. The orientation terms referred to in this publication, such as “above”, “below”, “before”, “after”, “left”, “right”, “inside”, “outside”, “side”, etc., are solely the orientation with reference to the additional schema. Therefore, the use of orientation terms is intended to illustrate and understand the disclosure, not to restrict the disclosure.

Drawings and illustrations are considered illustrative in nature and not restrictive. In the figures, structurally similar cells are represented with the same scale. Additionally, the size and thickness of each component shown in the drawings are arbitrarily shown, for the sake of understanding and ease of description, but the present publication is not limited to this.

Additionally, in the specification, unless explicitly described as opposed, the term “including” will be understood to mean including said components, but not excluding any other components. In addition, in the specification, “on”—means is positioned above or below the target assembly, while not means must be on top in a gravity-based direction.

To further elaborate on the technical means and efficacy employed by the disclosure to achieve a predetermined disclosure purpose, the following, in combination with the drawings and preferred examples, provide a detailed description of the structure, display panels, and display devices, the specific embodiments, structures, features, and their efficacy, of one OLED device proposed according to the disclosure.

### First Embodiment

Referring to FIG. 3, FIG. 3 is a schematic structural view of an OLED device structure in the embodiment. The first embodiment of the disclosure provides an OLED device structure, including: a first electrode 101, a self-assembled layer 102, a first transportation layer 104, a light-emitting layer (EML) 105, a second transportation layer 106 and a second electrode 108.

In particular, the self-assembled layer 102 is disposed on the first electrode 101, the first transportation layer 104 is disposed on the self-assembled layer 102, the light-emitting layer 105 is disposed on the first transportation layer 104, the second transportation layer 106 is disposed on the light-emitting layer 105, the second electrode 108 is disposed on the second transportation layer 106.

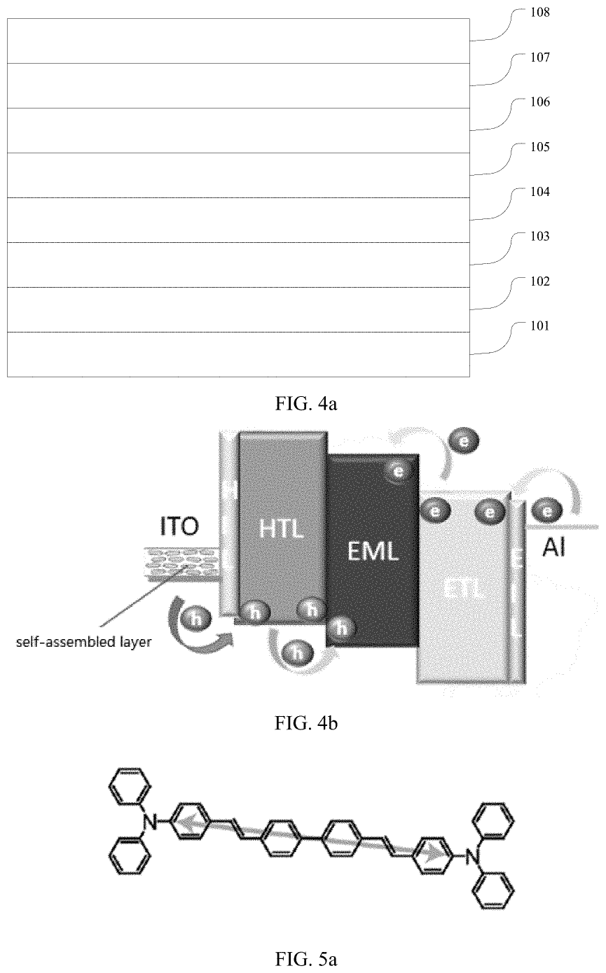

In addition, referring to FIG. 4a, FIG. 4a is a schematic structural view of another OLED device structure, FIG. 4b is a schematic structural view of the energy level of the OLED device structure, in the embodiment, the OLED device structure further includes a first injection layer 103 and a second injection layer 107, the first injection layer 103 is disposed between the first transportation layer and the self-assembled layer, the second injection layer 107 is disposed between the second transportation layer and the second electrode, a material of the self-assembled layer is prone to be horizontally oriented during a manufacturing process of the self-assembled layer.

In an embodiment, the material of the self-assembled layer includes heterocyclic conjugated long-chain linear molecules containing nitrogen or sulfur, and the manufacturing process of the self-assembled layer is an evaporation process or a solution coating process.

In an embodiment, the heterocyclic conjugated long-chain linear molecules containing nitrogen or sulfur include:

BDAVi (4,4′-Bis[4-(diphenylamino)styryl]biphenyl),

PEBA (4-(2,2-diphenylethyl)-N, N-bis(4-tolyl)aniline),

CBP (4,4′-Bis(N-carbazolyl)biphenyl),

PEDOT:PSS (poly(3,4-ethylenedioxythiophene):poly(styrenesulfonate)), and

Bpy-OXD (1,3-Bis[2-(2,2′-bipyridine-6)-1,3,4-oxadiazo-5]benzene).

In an embodiment, the first electrode is an anode, the first injection layer is a hole injection layer (HIL), the first transportation layer is a hole transportation layer (HTL), the second transportation layer is an electron transportation layer (ETL), the second injection layer is an electron injection layer (EIL), and the second electrode is a cathode.

In an embodiment, a material of the anode includes one or more selected from the group consisting of: indium tin oxide (ITO), indium zinc oxide (IZO), and zinc oxide (ZnO). A material of the hole injection layer includes one or more selected from the group consisting of: CuPc (29H, 31H-phthalocyaninato(2-)-N29, N30, N31, N32)copper), and TNATA (4, 4′, 4″-tris[2-naphthyl(phenyl)amino]triphenylamine). A material of the hole transportation layer includes one or more selected from the group consisting of: NPB (N,N′-bis-(1-naphthalenyl)-N, N′-bis-phenyl-(1,1′-biphenyl)-4, 4′-diamine), TPTE (N, N′-bis(Phenyl)-N, N′-bis(4′-(N, N-bis(Phenylamino)biphenyl-4-yl)benzidine), spiro-TAD (N, N′-bis(3-methylphenyl)-N, N′-diphenyl-9, 9-spirobifluorene-2, 7-diamine), BFA-1T (2(2(4, 4-Dimethyl-N, N′-diphenyl)-phenylthiophene), TDAB (1, 3, 5-tris (phenylamino) benzene), TDAPB (1, 3, 5-tri(p-pyrid-3-yl-phenyl)benzene), PTDATA (N1-phenyl-N4, N4-bis(4-(phenyl(m-tolyl)amino)phenyl)-N1-(m-tolyl)benzene-1,4-diamine), p-DPA-TDAB (1, 3, 5-tris(diphenylamino)benzene), and MTBDAB (4, 4′, 4″-tris(N-3-methylphenyl-N-diphenylamino) benzene). A material of the electron transportation layer includes one or more selected from the group consisting of: metal chelates, quinoline derivatives, oxaline derivatives, diazaanthracene derivatives and phenanthroline derivatives. A material of the electron injection layer includes one or more selected from the group consisting of: lithium oxide, lithium boron oxide, potassium silicon oxide, potassium carbonate, cesium carbonate, acetate (CH3COOR) and metal fluoride (RF). A material of the cathode includes one or more selected from the group consisting of: aluminum (Al), magnesium-silver alloy, and lithium aluminum alloy.

In an embodiment, the metal chelates include 6a-c, Mq3 (8-hydroxyquinoline M salt), FAlq3 (Mq3) (fluorinated hydroxyquinoline aluminum), Al(OXD)3 (aluminum oxadiazole), and Znq2 (8-hydroxyquinoline zinc). The oxaline derivatives include: BPQ (bis(phenylquinoxaline)) and TPQ (tris(phenylquinoxaline)).

In an embodiment, the R of the acetate (CH3COOR) includes: lithium (Li), sodium (Na), potassium (K), rubidium (Rb) or cesium (Cs); the R of the metal fluoride (RF) includes: Li, Na, K, Rb or Cs; and the M of the 8-Hydroxyquinoline M salt includes: aluminum (Al), gallium (Ga), or indium (In).

Specifically, to solve the problems existing in related art, this embodiment proposes OLED performance optimization through both aspects of OLED device structure design and material selection optimization.

Firstly, increasing the self-oriented self-assembled layer at the anode and the hole transportation layer by the evaporation process or the solution coating process, synchronization can also improve the ITO surface roughness, reduce the resistance value, increase the mobilities of the electrons and the holes, and elevate the emission rate of the bottom emission OLED. The materials mainly used for the self-assembled layer are: one that is prone to be oriented horizontally during electroless plating, including the self-assembled layer are heterocyclic conjugated long-chain linear molecules containing nitrogen or sulfur of BDAVBi, PEBA, CPB, PEDOT:PSS and Bpy-OXD. The driving force for self-assembly of the self-assembled layer mainly relies on the attractive and repulsive interactions of intermolecular force hydrogen bonds to finally achieve the purpose of horizontal orientation during the evaporation process; a thickness of the self-assembled layer (or self-calibrated layer) is generally controlled at 40˜200 Å.

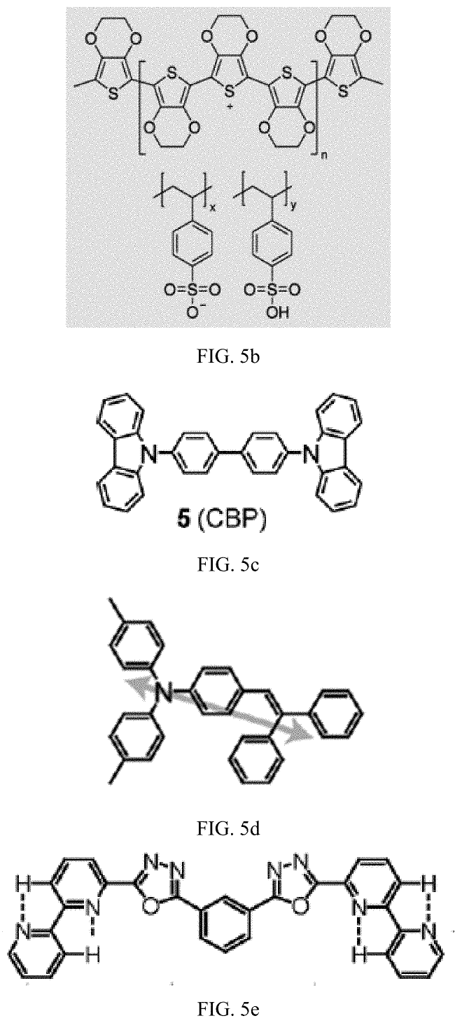

The schematic views of chemical structures of the above materials are shown in FIG. 5a, FIG. 5b, FIG. 5c, FIG. 5d and FIG. 5e. FIG. 5a is a schematic view of a chemical structure of BDAVBi in an embodiment, FIG. 5b is a schematic view of a chemical structure of PEBA in an embodiment, FIG. 5c is a schematic view of a chemical structure of CBP in an embodiment, FIG. 5d is a schematic view of a chemical structure of PEDOT:PSS in an embodiment, FIG. 5e is a schematic view of a chemical structure of Bpy-OXD in an embodiment.

Secondly, further in terms of other layer materials choices for the OLED device structure, generally all the fabrication processes by the evaporation process or the solution spin coating process were optimized and selected. For example, a thickness of the anode is generally controlled at 200˜1200 Å, and the material includes: indium tin oxide, indium zinc oxide, zinc oxide, etc; a thickness of the hole injection layer is generally controlled at 50-300 Å, and the material includes: CuPc and TNATA; a thickness of the hole transportation layer is generally controlled at 500˜2000 Å, and the material includes: NPB, TPTE, spiro-TAD, BFA-1T, TDAB, TDAPB, PTDATA, p-DPA-TDAB, MTBDAB; a thickness of the electron transportation layer is generally controlled at 100-500 Å, and the materials used are: metal chelates (6a-c, mq3 M=Al, GA, In, FALq3, Al (OXD) 3, Znq2), quinoline derivatives, oxaline derivatives (BPQ, TPQ), diazanthracene derivatives, and phenanthrene derivatives; a thickness of the electron injection layer is generally controlled at 10-200 Å, and the material includes: lithium oxide, lithium oxide boron, potassium silicon oxide, potassium carbonate, cesium carbonate, acetate (CH3COOR), R=Li, Na, K, Rb or CS, metal fluoride (RF), R=Li, Na, K, Rb or C; a thickness of the cathode is generally controlled at 1000-50000 Å, and the material includes: Al, magnesium silver alloy and lithium aluminum alloy.

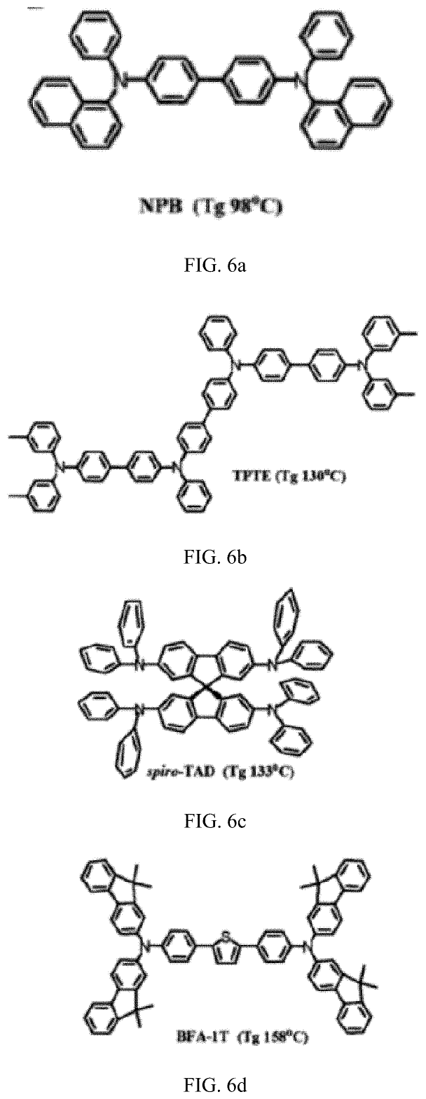

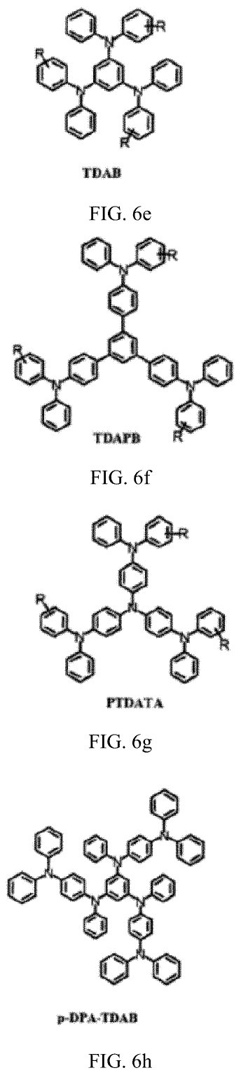

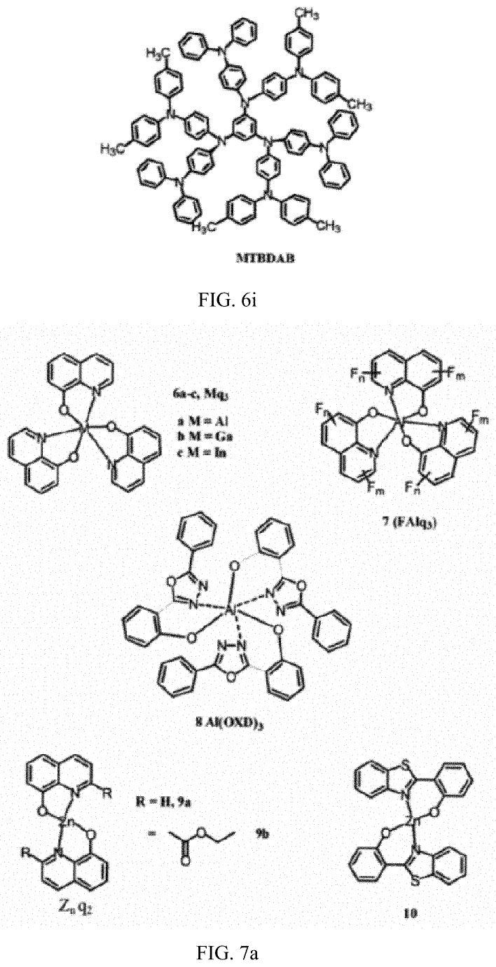

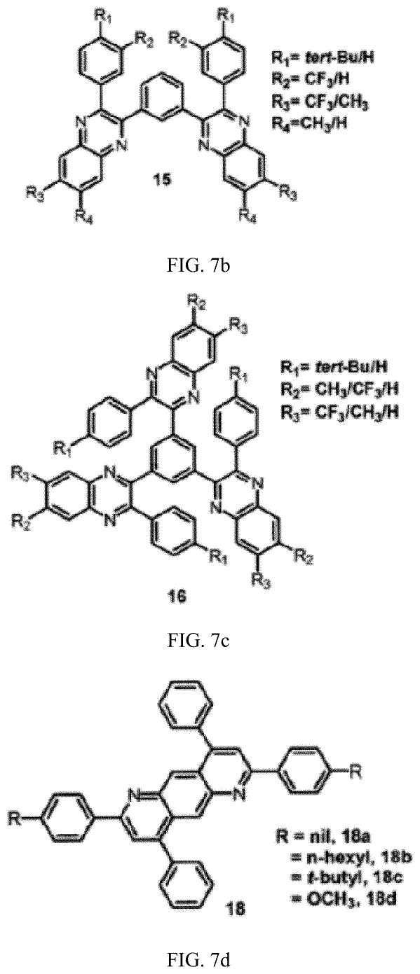

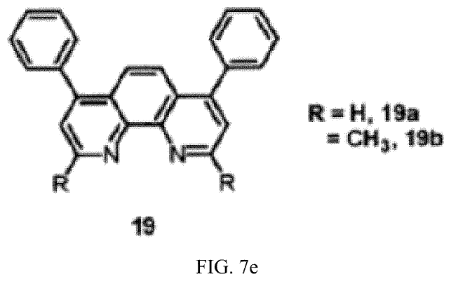

The schematic views of chemical structures of the above materials are shown in FIG. 6a, FIG. 6b, FIG. 6c, FIG. 6d, FIG. 6e, FIG. 6f, FIG. 6g, FIG. 6h, FIG. 6i, FIG. 7a, FIG. 7b, FIG. 7c, FIG. 7d and FIG. 7e. FIG. 6a is a schematic view of a chemical structure of NPB in an embodiment, FIG. 6b is a schematic view of a chemical structure of TPTE in an embodiment, FIG. 6c is a schematic view of a chemical structure of spiro-TAD in an embodiment, FIG. 6d is a schematic view of a chemical structure of BFA-1T in an embodiment, FIG. 6d is a schematic view of a chemical structure of BFA-1T in an embodiment, FIG. 6e is a schematic view of a chemical structure of TDAB in an embodiment, FIG. 6f is a schematic view of a chemical structure of TDAPB in an embodiment, FIG. 6g is a schematic view of a chemical structure of PTDATA in an embodiment, FIG. 6h is a schematic view of a chemical structure of p-DPA-TDAB in an embodiment, FIG. 6i is a schematic view of a chemical structure of MTBDAB in an embodiment, FIG. 7a is a schematic view of chemical structure of metal chelates in an embodiment, FIG. 7b is a schematic view of chemical structure of quinoline derivatives in an embodiment, FIG. 7c is a schematic view of chemical structure of oxaline derivatives in an embodiment, FIG. 7d is a schematic view of chemical structure of diazanthracene derivatives in an embodiment, and FIG. 7e is a schematic view of chemical structure of phenanthroline derivatives in an embodiment.

The disclosure can achieve the following effects by setting the self-oriented self-assembled layer in the OLED device structure and selecting specific materials:

1. Reduce the surface energy of ITO substrate, through a weak intermolecular force (hydrogen bond), an ITO work function is reduced, a Homo (Highest Occupied Molecular Orbital) of the HIL is improved, an energy gap between the ITO substrate and the HIL is reduced, a hole injection efficiency is improved, and a drive voltage is reduced;

2. Increases the mobilities of the electrons and the holes are increased by the π-π conjugation between the self-assembled layer and the HIL, and then a luminous efficiency is increased;

3. In order to improve an external quantum efficiency, the horizontally oriented molecules are disposed on the surface of the ITO substrate to increase an external light coupling efficiency and a light extraction rate.

### Second Embodiment

The second embodiment of the disclosure provides an OLED display panel, including the OLED device structure mentioned in the first embodiment.

In particular, the OLED device structure, as the key composition of the display panel of the disclosure, is the core of the normal display panel, the shell, the driving circuit, the control circuit, the optimization of optical taste adjustment and other technologies of the display panel, there have been many well-established prior technologies, not the focus of the disclosure, which can also be easily obtained and understood by those skilled in the art, and will not be further discussed here.

Preferably, the display panel of the embodiment for example include the OLED device structure as in first embodiment, which can improve an injection efficiency of hole, reduce a drive voltage, and increase mobilities of electron and hole, and then make a luminescence efficiency increase, increase an external light coupling efficiency, increase a light extraction rate, and improve an external quantum efficiency, etc., is an ideal structure and ideal technology that a novel display panel can adopt, and the implementation process of the structure of the specific OLED device can be referred to the first embodiment, here also not further discussed.

### Third Embodiment

The third embodiment of the disclosure provides a display device, including the OLED display panel mentioned in the second embodiment. The display panel is the core of the normal display of the display device, the shell, the driving circuit, the control circuit, the optimization of optical taste adjustment and other technologies of the display device, there have also been a lot of mature prior art, not the focus of the disclosure, the skilled person in the art can also be easily obtained and understood.

Specifically, the display device of the disclosure, for example, employing the OLED display panel described above, can be improved to lower the drive voltage so that the luminescence efficiency will increase, lift the external quantum efficiency, etc. the implementation process of the specific OLED device structure is referred to the first embodiment, and will not be further discussed here.

Terms “in some embodiments” and “in various embodiments” and the like are reused. The terms generally do not refer to the same embodiments; but it may also refer to the same embodiments. Terms “contains,” “has,” “and” includes” are synonymous unless their preceding and subsequent meanings reveal otherwise.

Finally, it should be noted that the above embodiments are only used to illustrate the technical solutions of the invention, rather than to limit the invention. Although the invention has been described in detail with reference to the foregoing embodiments, those of ordinary skill in the art should understand that the technical solutions illustrated in the foregoing embodiments may be modified, or some of the technical features may be equivalently substituted. These modifications or substitutions do not make the essence of corresponding technical solutions deviate from the spirit and scope of the technical solutions of various embodiments of the invention.

What is claimed is:

1. An organic light-emitting diode (OLED) device structure, comprising:
a first electrode;
a self-assembled layer, disposed on the first electrode;
a first transportation layer, disposed on the self-assembled layer;
a light-emitting layer, disposed on the first transportation layer;
a second transportation layer, disposed on the light-emitting layer; and
a second electrode, disposed on the second transportation layer.

2. The OLED device structure as claimed in claim 1, further comprising:
a first injection layer, disposed between the first transportation layer and the self-assembled layer; and
a second injection layer, disposed between the second transportation layer and the second electrode;
wherein a material of the self-assembled layer is prone to be horizontally oriented during a manufacturing process of the self-assembled layer.

3. The OLED device structure as claimed in claim 2, wherein the material of the self-assembled layer comprises heterocyclic conjugated long-chain linear molecules containing nitrogen or sulfur; and
wherein the manufacturing process of the self-assembled layer is an evaporation process or a solution coating process.

4. The OLED device structure as claimed in claim 3, wherein the heterocyclic conjugated long-chain linear molecules containing nitrogen or sulfur comprise:
4,4′-Bis[4-(diphenylamino)styryl] biphenyl;
4-(2,2-diphenylethyl)-N, N-bis(4-tolyl)aniline;
4,4′-Bis(N-carbazolyl) biphenyl;
poly(3,4-ethylenedioxythiophene):poly(styrenesulfonate); and
1,3-Bis[2-(2,2′-bipyridine-6)-1,3,4-oxadiazo-5] benzene.

5. The OLED device structure as claimed in claim 4, wherein the first electrode is an anode, the first injection layer is a hole injection layer, the first transportation layer is a hole transportation layer, the second transportation layer is an electron transportation layer, the second injection layer is an electron injection layer, and the second electrode is a cathode.

6. The OLED device structure as claimed in claim 5, wherein a material of the anode comprises one or more selected from the group consisting of indium tin oxide, indium zinc oxide, and zinc oxide;
wherein a material of the hole injection layer comprises one or more selected from the group consisting of:
29H, 31H-phthalocyaninato(2-)-N29, N30, N31, N32)copper, and 4, 4′, 4″-tris[2-naphthyl(phenyl)amino]triphenylamine;
wherein a material of the hole transportation layer comprises one or more selected from the group consisting of:
N, N′-bis-(1-naphthalenyl)-N, N′-bis-phenyl-(1,1′-biphenyl)-4, 4′-diamine,
N, N′-bis(phenyl)-N, N′-bis(4′-(N, N-bis(phenylamino)biphenyl-4-yl)benzidine,
N, N′-bis(3-methylphenyl)-N, N′-diphenyl-9,9-spirobifluorene-2,7-diamine,
2(2(4, 4-dimethyl-N, N′-diphenyl)-phenylthiophene,
1, 3, 5-tris(phenylamino)benzene,
1, 3, 5-tri(p-pyrid-3-yl-phenyl)benzene,
N1-phenyl-N4,N4-bis(4-(phenyl(m-tolyl)amino)phenyl)-N1-(m-tolyl)benzene-1, 4-diamine,
1, 3, 5-tris(diphenylamino)benzene, and
4,4′,4″-tris(N-3-methylphenyl-N-diphenylamino) benzene;
wherein a material of the electron transportation layer comprises one or more selected from the group consisting of: metal chelates, quinoline derivatives, oxaline derivatives, diazaanthracene derivatives and phenanthroline derivatives;
wherein a material of the electron injection layer comprises one or more selected from the group consisting of: lithium oxide, lithium boron oxide, potassium silicon oxide, potassium carbonate, cesium carbonate, acetate (CH3COOR), and metal fluoride (RF);
wherein a material of the cathode comprises one or more selected from the group consisting of: aluminum (Al), magnesium-silver alloy, and lithium aluminum alloy.

7. The OLED device structure as claimed in claim 6, wherein the metal chelates comprise: 8-hydroxyquinoline M salt, fluorinated hydroxyquinoline aluminum, aluminum oxadiazole (Al(OXD)₃), and 8-hydroxyquinoline zinc;
wherein the oxaline derivatives comprise: bis(phenylquinoxaline) and tris(phenylquinoxaline).

8. The OLED device structure as claimed in claim 7, wherein the R of the acetate (CH3COOR) comprises: lithium (Li), sodium (Na), potassium (K), rubidium (Rb) or cesium (Cs); the R of the metal fluoride (RF) comprises: Li, Na, K, Rb or Cs; and the M of the 8-Hydroxyquinoline M salt comprises: aluminum (Al), gallium (Ga), or indium (In).

9. An OLED display panel, comprising: an OLED device structure, wherein the OLED device structure comprises:
a first electrode;
a self-assembled layer, disposed on the first electrode;
a first transportation layer, disposed on the self-assembled layer;
a light-emitting layer, disposed on the first transportation layer;
a second transportation layer, disposed on the light-emitting layer; and
a second electrode, disposed on the second transportation layer.

10. The OLED display panel as claimed in claim 9, wherein the OLED device structure further comprises:
a first injection layer, disposed between the first transportation layer and the self-assembled layer; and
a second injection layer, disposed between the second transportation layer and the second electrode;
wherein a material of the self-assembled layer is prone to be horizontally oriented during a manufacturing process of the self-assembled layer.

11. The OLED display panel as claimed in claim 10, wherein the material of the self-assembled layer comprises heterocyclic conjugated long-chain linear molecules containing nitrogen or sulfur; and
wherein the manufacturing process of the self-assembled layer is an evaporation process or a solution coating process.

12. The OLED display panel as claimed in claim 11, wherein the heterocyclic conjugated long-chain linear molecules containing nitrogen or sulfur comprise:
4,4′-Bis[4-(diphenylamino)styryl] biphenyl;
4-(2,2-diphenylethyl)-N, N-bis(4-tolyl)aniline;
4,4′-Bis(N-carbazolyl) biphenyl;
poly(3,4-ethylenedioxythiophene): poly(styrenesulfonate); and
1,3-Bis[2-(2,2′-bipyridine-6)-1,3,4-oxadiazo-5] benzene.

13. The OLED display panel as claimed in claim 12, wherein the first electrode is an anode, the first injection layer is a hole injection layer, the first transportation layer is a hole transportation layer, the second transportation layer is an electron transportation layer, the second injection layer is an electron injection layer, and the second electrode is a cathode.

14. The OLED display panel as claimed in claim 13, wherein a material of the anode comprises one or more selected from the group consisting of indium tin oxide, indium zinc oxide, and zinc oxide;
wherein a material of the hole injection layer comprises one or more selected from the group consisting of:
29H, 31H-phthalocyaninato(2-)-N29, N30, N31, N32)copper, and 4, 4′, 4″-tris[2-naphthyl(phenyl)amino]triphenylamine;
wherein a material of the hole transportation layer comprises one or more selected from the group consisting of:
N, N′-bis-(1-naphthalenyl)-N, N′-bis-phenyl-(1,1′-biphenyl)-4, 4′-diamine,
N, N′-bis(phenyl)-N, N′-bis(4′-(N, N-bis(phenylamino)biphenyl-4-yl)benzidine,
N, N′-bis(3-methylphenyl)-N, N′-diphenyl-9,9-spirobifluorene-2,7-diamine,
2(2(4, 4-dimethyl-N, N′-diphenyl)-phenylthiophene,
1, 3, 5-tris(phenylamino)benzene,
1, 3, 5-tri(p-pyrid-3-yl-phenyl)benzene,
N1-phenyl-N4,N4-bis(4-(phenyl(m-tolyl)amino)phenyl)-N1-(m-tolyl)benzene-1, 4-diamine,
1, 3, 5-tris(diphenylamino)benzene, and
4,4′,4″-tris(N-3-methylphenyl-N-diphenylamino) benzene;
wherein a material of the electron transportation layer comprises one or more selected from the group consisting of: metal chelates, quinoline derivatives, oxaline derivatives, diazaanthracene derivatives and phenanthroline derivatives;
wherein a material of the electron injection layer comprises one or more selected from the group consisting of: lithium oxide, lithium boron oxide, potassium silicon oxide, potassium carbonate, cesium carbonate, acetate (CH3COOR), and metal fluoride (RF);
wherein a material of the cathode comprises one or more selected from the group consisting of: aluminum (Al), magnesium-silver alloy, and lithium aluminum alloy.

15. The OLED display panel as claimed in claim 14, wherein the metal chelates comprise: 8-hydroxyquinoline M salt, fluorinated hydroxyquinoline aluminum, aluminum oxadiazole (Al(OXD)₃), and 8-hydroxyquinoline zinc;
wherein the oxaline derivatives comprise: bis(phenylquinoxaline) and tris(phenylquinoxaline).

16. The OLED display panel as claimed in claim 15, wherein the R of the acetate (CH3COOR) comprises: lithium (Li), sodium (Na), potassium (K), rubidium (Rb) or cesium (Cs); the R of the metal fluoride (RF) comprises: Li, Na, K, Rb or Cs; and the M of the 8-Hydroxyquinoline M salt comprises: aluminum (Al), gallium (Ga), or indium (In).

17. A display device comprising an OLED display panel including an OLED device structure, wherein the OLED device structure comprises:
a first electrode;
a self-assembled layer, disposed on the first electrode;
a first transportation layer, disposed on the self-assembled layer;
a light-emitting layer, disposed on the first transportation layer;
a second transportation layer, disposed on the light-emitting layer; and
a second electrode, disposed on the second transportation layer.

18. The OLED display panel as claimed in claim 17, wherein the OLED device structure further comprises:
a first injection layer, disposed between the first transportation layer and the self-assembled layer; and
a second injection layer, disposed between the second transportation layer and the second electrode;
wherein a material of the self-assembled layer is prone to be horizontally oriented during a manufacturing process of the self-assembled layer.

19. The display device as claimed in claim 18, wherein the material of the self-assembled layer comprises heterocyclic conjugated long-chain linear molecules containing nitrogen or sulfur; and
wherein the manufacturing process of the self-assembled layer is an evaporation process or a solution coating process; and
wherein the heterocyclic conjugated long-chain linear molecules containing nitrogen or sulfur comprise:
4,4′-Bis[4-(diphenylamino)styryl] biphenyl;
4-(2,2-diphenylethyl)-N, N-bis(4-tolyl)aniline;
4,4′-Bis(N-carbazolyl) biphenyl;
poly(3,4-ethylenedioxythiophene): poly(styrenesulfonate); and
1,3-Bis[2-(2,2′-bipyridine-6)-1,3,4-oxadiazo-5] benzene.

20. The display device as claimed in claim 19, wherein the first electrode is an anode, the first injection layer is a hole injection layer, the first transportation layer is a hole transportation layer, the second transportation layer is an electron transportation layer, the second injection layer is an electron injection layer, and the second electrode is a cathode;
wherein a material of the anode comprises one or more selected from the group consisting of indium tin oxide, indium zinc oxide, and zinc oxide;
wherein a material of the hole injection layer comprises one or more selected from the group consisting of:
29H, 31H-phthalocyaninato(2-)-N29, N30, N31, N32)copper, and 4, 4′, 4″-tris[2-naphthyl(phenyl)amino]triphenylamine;
wherein a material of the hole transportation layer comprises one or more selected from the group consisting of:
N, N′-bis-(1-naphthalenyl)-N, N′-bis-phenyl-(1,1′-biphenyl)-4, 4′-diamine,
N, N′-bis(phenyl)-N, N′-bis(4′-(N, N-bis(phenylamino)biphenyl-4-yl)benzidine,
N, N′-bis(3-methylphenyl)-N, N′-diphenyl-9,9-spirobifluorene-2,7-diamine,
2(2(4, 4-dimethyl-N, N′-diphenyl)-phenylthiophene,
1, 3, 5-tris(phenylamino)benzene,
1, 3, 5-tri(p-pyrid-3-yl-phenyl)benzene,
N1-phenyl-N4,N4-bis(4-(phenyl(m-tolyl)amino)phenyl)-N1-(m-tolyl)benzene-1, 4-diamine,
1, 3, 5-tris(diphenylamino)benzene, and
4,4′,4″-tris(N-3-methylphenyl-N-diphenylamino) benzene;
wherein a material of the electron transportation layer comprises one or more selected from the group consisting of: metal chelates, quinoline derivatives, oxaline derivatives, diazaanthracene derivatives and phenanthroline derivatives;
wherein a material of the electron injection layer comprises one or more selected from the group consisting of: lithium oxide, lithium boron oxide, potassium silicon oxide, potassium carbonate, cesium carbonate, acetate (CH3COOR), and metal fluoride (RF);
wherein a material of the cathode comprises one or more selected from the group consisting of: aluminum (Al), magnesium-silver alloy, and lithium aluminum alloy.
